(19) United States
(12) Patent Application Publication
(10) Pub. No.: US 2023/0420348 A1
(43) Pub. Date: Dec. 28, 2023

(54) SINX ADHESION PROMOTER WITH ADHESION HOLE FEATURES IN PACKAGING SUBSTRATE FOR RELIABILITY PERFORMANCE ENHANCEMENT

(71) Applicant: Intel Corporation, Santa Clara, CA (US)

(72) Inventors: Jieying KONG, Chandler, AZ (US); Whitney BRYKS, Tempe, AZ (US); Dilan SENEVIRATNE, Chandler, AZ (US); Suddhasattwa NAD, Chandler, AZ (US); Srinivas V. PIETAMBARAM, Chandler, AZ (US)

(21) Appl. No.: 17/852,039

(22) Filed: Jun. 28, 2022

(51) Int. Cl. H01L 23/498; H01L 21/48

(52) U.S. Cl. CPC H01L 23/49822; H01L 23/49894; H01L 21/4857; H01L 2224/16225; H01L 24/16

(57) ABSTRACT

Embodiments disclosed herein include electronic packages. In an embodiment, the electronic package comprises a first layer, where the first layer is a dielectric material, and a trace on the first layer. In an embodiment, a pad is on the first layer, and a liner is over the first layer, the trace, and the pad, where a hole is provided through the liner. In an embodiment, the electronic package further comprises a second layer over the first layer, the trace, the pad, and the liner.

### TECHNICAL FIELD

Embodiments of the present disclosure relate to electronic packages, and more particularly to packaging architectures that include smooth copper traces with a SiNx adhesion promoting layer that includes adhesion holes.

### BACKGROUND

In electronic packaging architectures, copper traces in the package substrate are roughened (e.g., with an etching process or the like) prior to lamination of the subsequent layer. The roughened surface allows for an improvement in the adhesion between layers. This enables a more robust package substrate. However, the rough copper surface is detrimental to insertion loss. Currently, it is difficult to meet insertion loss targets for advanced high speed input/output (HSIO) interconnect architectures, particularly when the copper is roughened. One solution to meet the insertion loss targets is to utilize smooth copper traces. That is, the copper traces are formed and there is no subsequent roughening process. The smoother surface of the copper enables insertion losses that are more compatible with HSIO interconnect architectures. Unfortunately, the smooth copper traces do not adhere well to the overlying buildup layers. As such, the robustness of the package substrate is decreased.

In order to accommodate smooth copper traces, it has been proposed to use an adhesion promoting liner. The adhesion promoting liner is deposited with a blanket deposition process. Accordingly, the adhesion promoting liner is formed over the entire dielectric buildup layer in addition to the copper traces. This is problematic since the adhesion promoting layer blocks the ability to outgas the underlying buildup layer. Additionally, the pads are covered by the adhesion promoting liner. This portion of the adhesion promoting liner needs to be removed in order to make connections between the layers of the package substrate.

### BRIEF DESCRIPTION OF THE DRAWINGS

FIG. 1A is a cross-sectional illustration of a layer of a package substrate with traces, a pad, and a liner over the traces and pad.

FIG. 1B is a cross-sectional illustration of the layer after a second layer is disposed over the first layer and a via opening is formed.

FIG. 1C is a cross-sectional illustration of the package substrate after the liner in the via opening is removed.

FIG. 2A is a cross-sectional illustration of a package substrate with a first layer, traces, and a pad, in accordance with an embodiment.

FIG. 2B is a cross-sectional illustration of the package substrate after mask features are formed over the first layer and the pad, in accordance with an embodiment.

FIG. 2C is a cross-sectional illustration of the package substrate after a liner is deposited, in accordance with an embodiment.

FIG. 2D is a cross-sectional illustration of the package substrate after the mask features are removed, in accordance with an embodiment.

FIG. 2E is a cross-sectional illustration of the package substrate after a second layer is provided over the first layer and a via opening is formed, in accordance with an embodiment.

FIG. 2F is a cross-sectional illustration of the package substrate after second traces and a second pad are formed over the second layer, in accordance with an embodiment.

FIG. 3A is a cross-sectional illustration of a package substrate after a liner is deposited with a mask feature over the first layer, in accordance with an embodiment.

FIG. 3B is a cross-sectional illustration of the package substrate after the mask layer is removed, in accordance with an embodiment.

FIG. 3C is a cross-sectional illustration of the package substrate after a second layer with a via opening is disposed over the first layer, in accordance with an embodiment.

FIG. 3D is a cross-sectional illustration of the package substrate after second traces and a second pad are formed over the second layer, in accordance with an embodiment.

FIG. 4A is a cross-sectional illustration of a package substrate with traces and a pad formed over a first layer, in accordance with an embodiment.

FIG. 4B is a cross-sectional illustration of the package substrate after a liner is provided over the traces, the pad, and the first layer, in accordance with an embodiment.

FIG. 4C is a cross-sectional illustration of the package substrate after a photoresist is provided over the first layer, in accordance with an embodiment.

FIG. 4D is a cross-sectional illustration of the package substrate after openings are patterned into the photoresist, in accordance with an embodiment.

FIG. 4E is a cross-sectional illustration of the package substrate after the liner is removed from the openings in the photoresist, in accordance with an embodiment.

FIG. 4F is a cross-sectional illustration of the package substrate after the photoresist is removed, in accordance with an embodiment.

FIG. 4G is a cross-sectional illustration of the package substrate after a second layer with a via opening is formed over the first layer, in accordance with an embodiment.

FIG. 4H is a cross-sectional illustration of the package substrate after second traces and a second pad are formed over the second layer, in accordance with an embodiment.

FIG. 5 is a cross-sectional illustration of a package substrate with a plurality of layers with liner openings, in accordance with an embodiment.

FIG. 6 is a cross-sectional illustration of an electronic system with a package substrate that includes a plurality of layers with liner openings, in accordance with an embodiment.

FIG. 7 is a schematic of a computing device built in accordance with an embodiment.

### EMBODIMENTS OF THE PRESENT DISCLOSURE

Described herein are packaging architectures that include smooth copper traces with a SiNx adhesion promoting layer that includes adhesion holes, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

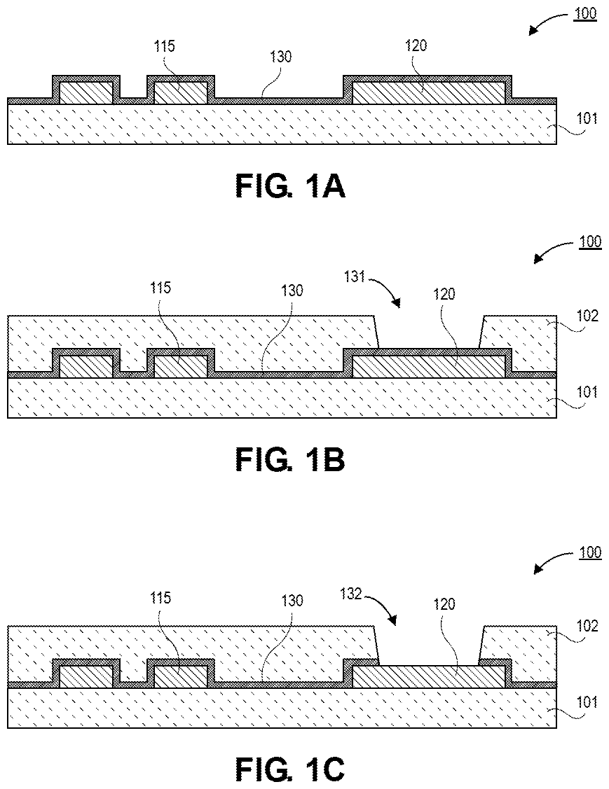

Referring now to FIGS. 1A-1C, a series of cross-sectional illustrations depicting a process for forming a package substrate 100 is shown in order to provide context for embodiments disclosed herein. The fabrication process includes the addition of a liner 130 over a pad 120 and traces 115 in order to improve adhesion.

Referring now to FIG. 1A, a cross-sectional illustration of a package substrate 100 is shown. The package substrate 100 may include a first layer 101. The first layer 101 may be a bottommost layer of the package substrate 100. In other implementations, the first layer 101 may be the first layer over a core (not shown). The first layer 101 may also be formed over underlying buildup layers (not shown). The first layer 101 may be a dielectric buildup film.

One or more traces 115 may be provided on the first layer 101. Additionally, one or more pads 120 may be included on the first layer 101. The traces 115 and pads 120 may be formed with any suitable patterning process. In a particular implementation, the traces 115 and the pad 120 may include smooth surfaces. That is, the surfaces may not be roughened with an etching process or the like. As such, a liner 130 may need to be provided over the traces 115 and the pad 120 in order to improve adhesion to a subsequently added second layer. As shown, the liner 130 is provided over sidewalls and top surfaces of the traces 115 and the pads 120. Additionally, the liner 130 is provided over exposed portions of the first layer 101. Unfortunately, providing the liner 130 over the first layer 101 prevents the first layer 101 from fully outgassing. As such, there are reliability concerns in the package substrate 100.

Referring now to FIG. 1B, a cross-sectional illustration of the package substrate after a second layer 102 is laminated over the first layer 101 is shown. In an embodiment, the second layer 102 may be substantially similar to the first layer 101. The second layer 102 may be patterned to form an opening 131. The opening 131 may be provided over the pad 120. The opening 131 may be formed with a laser drilling process. As such, the opening 131 may have tapered sidewall. The opening 131 may expose a portion of the liner 130 over the pad 120.

Referring now to FIG. 1C, a cross-sectional illustration of the package substrate 100 after the liner 130 over the pad 120 is removed is shown. The liner 130 may be removed with a dry etching process or the like. The removal of the liner 130 may result in the formation of opening 132 through the second layer 102 and the liner 130. After removal of portions of the liner 130, a top surface of the pad 120 is exposed. A subsequently formed via may be in direct contact with the pad 120.

As shown, the liner 130 architecture used in FIGS. 1A-1C has several drawbacks. One drawback is that the liner 130 provides a barrier between the first layer 101 and the second layer 102. As such, there is no path that allows for outgassing of the first layer 101. This creates a reliability risk for the package substrate 100. Additionally, a dry etching process may be needed in order to expose the pad 120. As such, manufacturing operations are added, which increases costs and decreases throughput.

Accordingly, embodiments disclosed herein include package substrates that include adhesion promoting liners that include holes to allow for outgassing. Additionally, openings may be formed in the liner over pads in order to allow for connecting between layers without additional processing operations. In an embodiment, the traces and pads are formed with standard processes and are left with smooth copper surfaces in order to improve insertion loss characteristics. The adhesion promoting liner is then selectively patterned in order to form openings for outgassing and electrical connection between layers.

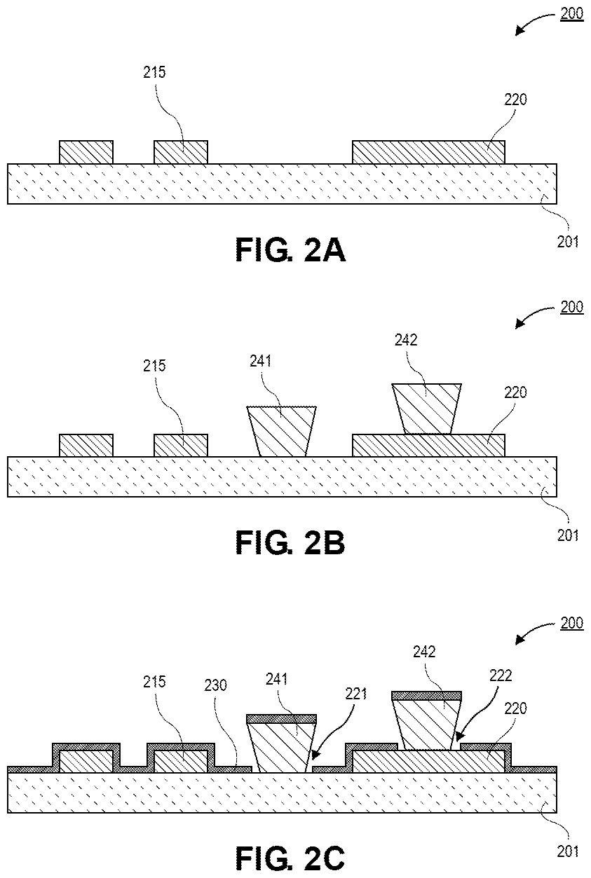

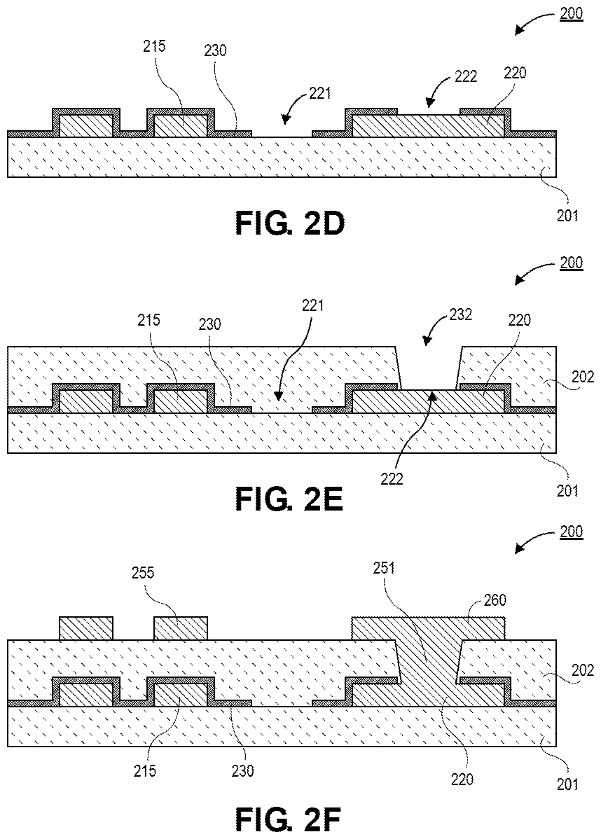

Referring now to FIGS. 2A-2F, a series of cross-sectional illustrations depicting a process for forming a package substrate 200 is shown, in accordance with an embodiment. In an embodiment, the package substrate 200 includes an adhesion promoting liner that allows for good adhesion between the metal features (e.g., traces 215 and pads 220) and the overlying layer, without needing to roughen the metal features.

Referring now to FIG. 2A, a cross-sectional illustration of a package substrate 200 is shown, in accordance with an embodiment. In an embodiment, the package substrate 200 includes a first layer 201. The first layer 201 may be a dielectric layer, such as a buildup film. The first layer 201 may be a bottommost layer of the package substrate 200. In other embodiments, the first layer 201 may be the first layer over a core (not shown). Additionally, one or more layers may be provided below the first layer 201 in some embodiments.

In an embodiment, one or more traces 215 may be provided on the first layer 201. Additionally, one or more pads 220 may be provided on the first layer 201. The traces 215 and pads 220 may be formed with any suitable processing operations. For example, a semi-additive process (SAP) operation may be used in order to form the traces 215 and the pads 220. In an embodiment, the traces 215 and the pads 220 may have smooth surfaces as a result of the deposition process. That is, the traces 215 and 220 may not be roughened (e.g., with an etching process) subsequent to their formation. The smooth surfaces of the traces 215 and pads 220 improves insertion loss characteristics of the package substrate 200. In an embodiment, the traces 215 and 220 may include copper or any other suitable conductive material composition.

Referring now to FIG. 2B, a cross-sectional illustration of the package substrate 200 after mask features 241 and 242 are formed is shown, in accordance with an embodiment. In an embodiment, mask feature 241 may be provided over the first layer 201. For example, the mask feature 241 may be provided on the first layer 201 between a trace 215 and a pad 220. In an embodiment, mask feature 242 may be provided on the pad 220. The mask features 241 and 242 may be part of a patterned photoresist material. In an embodiment, the shape of the mask features 241 and 242 may be optimized in order to allow for easy stripping of the mask features 241 and 242 in a subsequent processing operation. For example, the mask features 241 and 242 may have a top surface that is wider than a bottom surface.

Referring now to FIG. 2C, a cross-sectional illustration of the package substrate 200 after a liner 230 is deposited is shown, in accordance with an embodiment. In an embodiment, the liner 230 may be a material that improves adhesion between the traces 215 and pad 220 and an overlying layer deposited in a subsequent processing operation. For example, the liner 230 may comprise silicon and nitrogen (e.g., SiNx) in some embodiments. In an embodiment, the liner 230 may be deposited with a blanket deposition process. For example, the liner 230 may be deposited with a physical vapor deposition (PVD) process or the like.

As shown, the mask features 241 and 242 block the deposition of the liner 230 over a portion of the first layer 201 and a portion of the pad 220. For example, the liner 230 may include an opening 221 over the first layer 201, and an opening 222 over the pad 220. The liner 230 may deposit on the top surface of the mask features 241 and 242. In some embodiments, portions of the liner 230 may also deposit along sidewalls of the mask features 241 and 242.

Referring now to FIG. 2D, a cross-sectional illustration of the package substrate 200 after the mask features 241 and 242 are removed is shown, in accordance with an embodiment. In an embodiment, the mask features 241 and 242 may be removed with any suitable process. For example, the mask features 241 and 242 may be removed with a resist stripping process or the like. The removal of the mask features 241 and 242 exposes the openings 221 and 222 through the liner 230. As such, the liner 230 is provided over the sidewalls and top surface of the traces 215, and over the sidewalls and a portion of the top surface of the pad 220. The liner 230 may also be provided over the top surface of the first layer 201 with the exception of the opening 221. While a single opening 221 is shown on the first layer 201, it is to be appreciated that any number of openings 221 may be provided on the first layer 201.

Referring now to FIG. 2E, a cross-sectional illustration of the package substrate 200 after a second layer 202 is deposited over the first layer 201 is shown, in accordance with an embodiment. In an embodiment, the second layer 202 may be substantially similar to the first layer 201. The second layer 202 may be deposited over the first layer 201 with a lamination process or the like. In an embodiment, the second layer 202 has good adhesion to the traces 215 and the pad 220 due to the presence of the liner 230. Additionally, portions of the second layer 202 may directly contact the first layer 201 through the opening 221 in the liner 230.

In an embodiment, a via opening 232 may be patterned through the second layer 202. The via opening 232 may expose a portion of the pad 220. In an embodiment, the via opening 232 may have a width that is smaller than a width of the opening 222. As such, the via opening 232 may not expose portions of the liner 230 over the pad 220 in some embodiments. The via opening 232 may be formed with a laser drilling process or the like.

Referring now to FIG. 2F, a cross-sectional illustration of the package substrate 200 after second traces 255 and a second pad 260 are formed is shown, in accordance with an embodiment. In an embodiment, the second traces 255 and the second pad 260 may be formed with any suitable deposition process. In an embodiment, a via 251 may also fill the via opening 232. The via 251 provides electrical coupling between the pad 220 and the second pad 260. In a particular embodiment, the via 251 does not contact a portion of the liner 230. The second traces 255 and the second pad 260 may have smooth surfaces. A second liner (not shown) may be deposited over the second traces 255 and the second pad 260 with a process similar to the process described above for forming the liner 230.

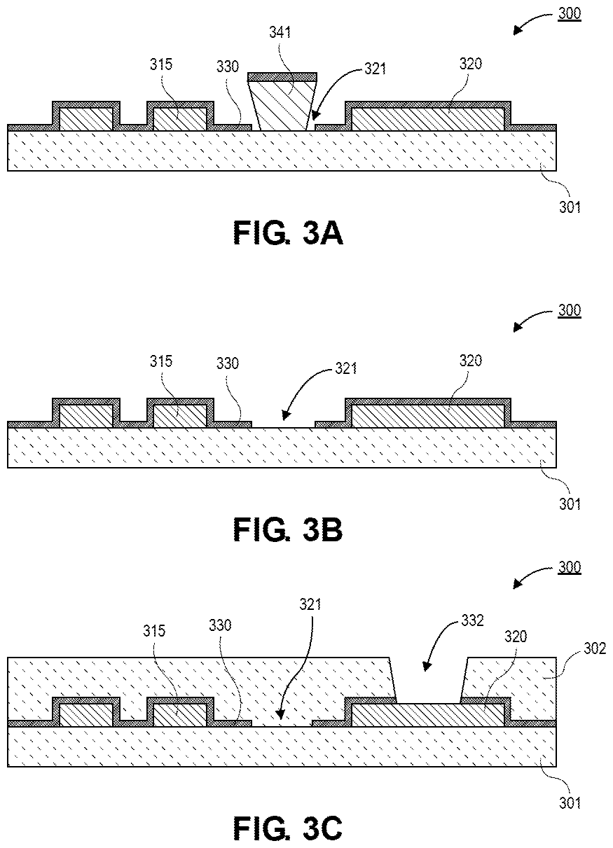

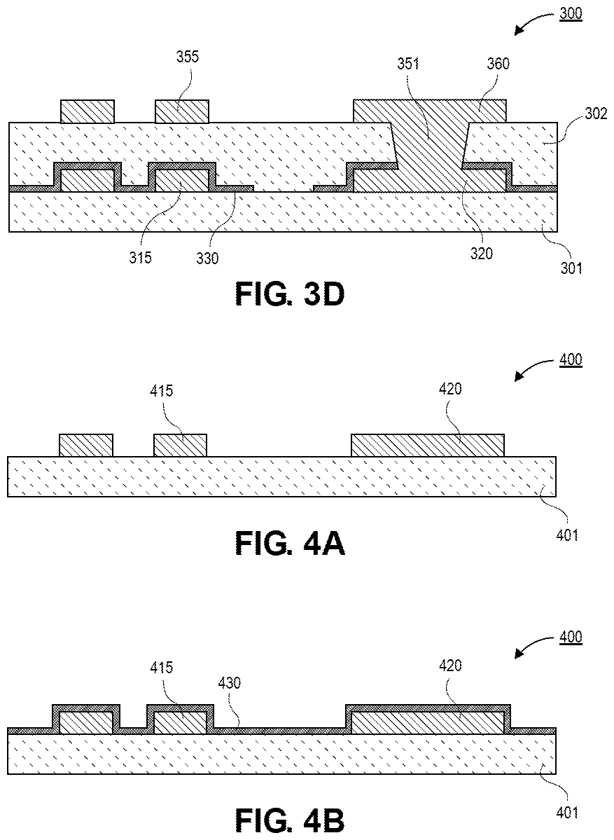

Referring now to FIGS. 3A-3D, a series of cross-sectional illustrations depicting a process for forming a package substrate 300 is shown, in accordance with an embodiment. The embodiment shown in FIGS. 3A-3D is similar to the process shown in FIGS. 2A-F with the exception of there not being a mask feature disposed over the pad.

Referring now to FIG. 3A, a cross-sectional illustration of a package substrate 300 is shown, in accordance with an embodiment. In an embodiment, the package substrate 300 may include a first layer 301. The first layer 301 may be any layer in a stack of a package substrate. The first layer 301 may be a dielectric buildup film. In an embodiment, traces 315 and a pad 320 are provided over the first layer 301. In an embodiment, the traces 315 and 320 have smooth surfaces.

In an embodiment, a mask feature 341 is provided over the first layer 301. The mask feature 341 may be provided between a trace 315 and the pad 320, though it is to be appreciated that the mask feature 341 may be provided at any location. In an embodiment, a liner 330 is deposited over the first layer 301. The liner 330 may be an adhesion promoting liner 330. For example, the liner 330 may comprise silicon and nitrogen (e.g., SiNx). The liner 330 may be deposited with a blanket deposition process, such as a PVD process or the like. The mask feature 341 blocks the deposition of the liner 330 over a portion of the first layer 301. As such, an opening 321 is provided through the liner 330.

Referring now to FIG. 3B, a cross-sectional illustration of the package substrate 300 after the mask feature 341 is removed is shown, in accordance with an embodiment. In an embodiment, the mask feature 341 may be removed with any suitable process. For example, the mask feature 341 may be removed with a resist stripping process or the like. The removal of the mask feature 341 exposes the opening 321 through the liner 330. As such, the liner 330 is provided over the sidewalls and top surface of the traces 315, and over the sidewalls and a top surface of the pad 320. The liner 330 may also be provided over the top surface of the first layer 301 with the exception of the opening 321. While a single opening 321 is shown on the first layer 301, it is to be appreciated that any number of openings 321 may be provided on the first layer 301.

Referring now to FIG. 3C, a cross-sectional illustration of the package substrate 300 after a second layer 302 is provided over the first layer 301 is shown, in accordance with an embodiment. In an embodiment, the second layer 302 may be substantially similar to the first layer 301. The second layer 302 may be deposited over the first layer 301 with a lamination process or the like. In an embodiment, the second layer 302 has good adhesion to the traces 315 and the pad 320 due to the presence of the liner 330. Additionally, portions of the second layer 302 may directly contact the first layer 301 through the opening 321 in the liner 330.

In an embodiment, a via opening 332 may be patterned through the second layer 302 and the liner 330. The via opening 332 may expose a portion of the pad 320. The via opening 332 may be formed with a laser drilling process or the like. The laser drilling process may also remove portions of the liner 330 over the pad 320. In other embodiments, a separate etching process may be used in order to remove the liner 330 and expose the pad 320.

Referring now to FIG. 3D, a cross-sectional illustration of the package substrate 300 after second traces 355 and a second pad 360 are formed is shown, in accordance with an embodiment. In an embodiment, the second traces 355 and the second pad 360 may be formed with any suitable deposition process. In an embodiment, a via 351 may also fill the via opening 332. The via 351 provides electrical coupling between the pad 320 and the second pad 360. In a particular embodiment, the via 351 contacts a portion of the liner 330 (e.g., a sidewall surface of the liner 330). The second traces 355 and the second pad 360 may have smooth surfaces. A second liner (not shown) may be deposited over the second traces 355 and the second pad 360 with a process similar to the process described above for forming the liner 330.

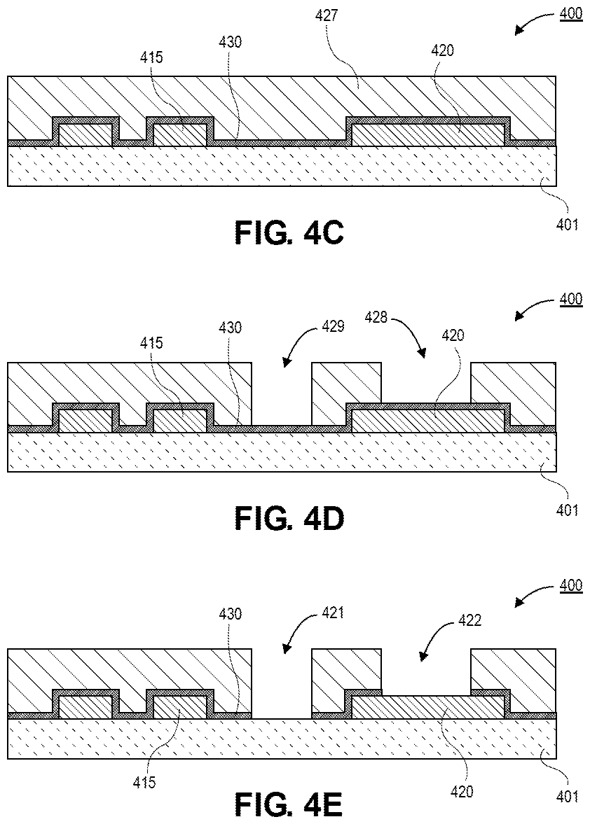

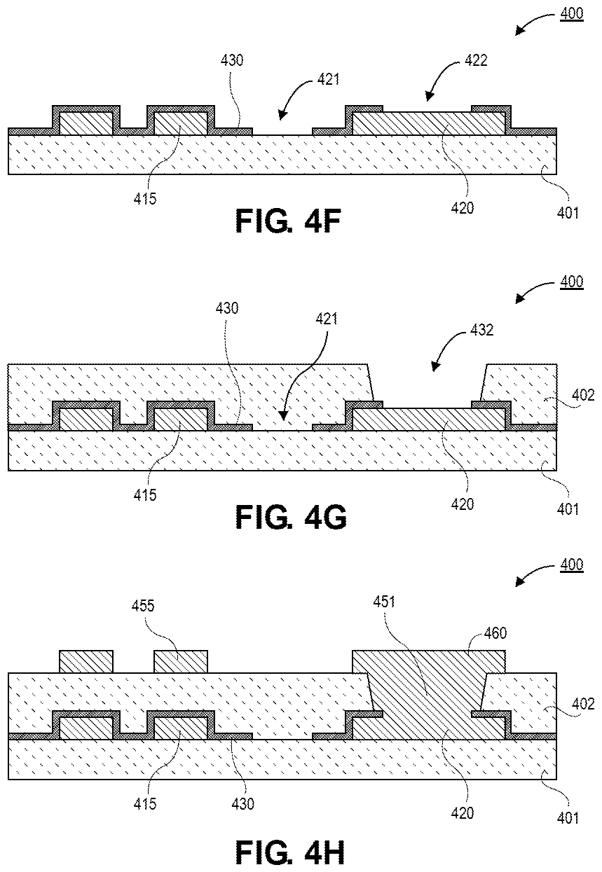

Referring now to FIGS. 4A-4H, a series of cross-sectional illustrations depicting a process for forming a package substrate 400 is shown, in accordance with an embodiment. In an embodiment, the package substrate 400 is formed with a blanket liner deposition process. The liner is then patterned with an etching process to form openings for electrical coupling and moisture outgassing.

Referring now to FIG. 4A, a cross-sectional illustration of a package substrate 400 is shown, in accordance with an embodiment. In an embodiment, the package substrate 400 includes a first layer 401. The first layer 401 may be a dielectric layer, such as a buildup film. The first layer 401 may be any layer of a package substrate 400.

In an embodiment, one or more traces 415 may be provided on the first layer 401. Additionally, one or more pads 420 may be provided on the first layer 401. The traces 415 and pads 420 may be formed with any suitable processing operations. For example, an SAP operation may be used in order to form the traces 415 and the pads 420. In an embodiment, the traces 415 and the pads 420 may have smooth surfaces as a result of the deposition process. That is, the traces 415 and 420 may not be roughened (e.g., with an etching process) subsequent to their formation. The smooth surfaces of the traces 415 and pads 420 improves insertion loss characteristics of the package substrate 400. In an embodiment, the traces 415 and 420 may include copper or any other suitable conductive material composition.

Referring now to FIG. 4B, a cross-sectional illustration of the package substrate 400 after a liner 430 is deposited is shown, in accordance with an embodiment. In an embodiment, the liner 430 may be deposited with a blanket deposition process. For example, a PVD process or the like may be used to deposit the liner 430. The liner 430 may cover sidewall surfaces and a top surface of the traces 415 and the pad 420. In an embodiment, the liner 430 also covers the exposed top surfaces of the first layer 401. The liner 430 may be a material that promotes adhesion with an overlying layer. For example, the liner 430 may comprise silicon and nitrogen (e.g., SiNx).

Referring now to FIG. 4C, a cross-sectional illustration of the package substrate 400 after a photoresist layer 427 is provided over the first layer 401 is shown, in accordance with an embodiment. As shown, the photoresist layer 427 covers the traces 415 and the pad 420. The photoresist layer 427 may be formed with a spin coating process or any other suitable process.

Referring now to FIG. 4D, a cross-sectional illustration of the package substrate 400 after the photoresist layer 427 is patterned is shown, in accordance with an embodiment. In an embodiment, openings 429 and 428 may be provided through the photoresist layer 427. The opening 429 may expose a portion of the liner 430 that is directly over the first layer 401. The opening 428 may expose a portion of the liner 430 that is directly over the pad 420.

Referring now to FIG. 4E, a cross-sectional illustration of the package substrate 400 after the liner 430 is patterned is shown, in accordance with an embodiment. In an embodiment, the liner 430 may be patterned with a dry etching process. The removal of the liner 430 forms an opening 421 that is over the first layer 401 and an opening 422 that is over the pad 420.

Referring now to FIG. 4F, a cross-sectional illustration of the package substrate 400 after the photoresist layer 427 is removed is shown, in accordance with an embodiment. In an embodiment, the photoresist layer 427 may be removed with a stripping process or the like.

Referring now to FIG. 4G, a cross-sectional illustration of the package substrate 400 after a second layer 402 is provided over the first layer 401 is shown, in accordance with an embodiment. In an embodiment, the second layer 402 may be substantially similar to the first layer 401. The second layer 402 may be deposited over the first layer 401 with a lamination process or the like. In an embodiment, the second layer 402 has good adhesion to the traces 415 and the pad 420 due to the presence of the liner 430. Additionally, portions of the second layer 402 may directly contact the first layer 401 through the opening 421 in the liner 430.

In an embodiment, a via opening 432 may be patterned through the second layer 402. The via opening 432 may expose a portion of the pad 420. A width of the via opening 432 may be greater than a width of the opening 422. As such, a portion of the top surface of the liner 430 may be exposed in some embodiments. While shown with a width of opening 432 being greater than the width of the opening 422, it is to be appreciated that embodiments are not limited to such configurations. For example, the width of the opening 432 may be the same width or narrower than the width of the opening 422. In such an embodiment, the top surface of the liner 430 may not be exposed. The via opening 432 may be formed with a laser drilling process or the like.

Referring now to FIG. 4H, a cross-sectional illustration of the package substrate 400 after second traces 455 and a second pad 460 are formed is shown, in accordance with an embodiment. In an embodiment, the second traces 455 and the second pad 460 may be formed with any suitable deposition process. In an embodiment, a via 451 may also fill the via opening 432. The via 451 provides electrical coupling between the pad 420 and the second pad 460. In a particular embodiment, the via 451 contacts a portion of the liner 430 (e.g., top surfaces and sidewall surfaces of the liner 430). The second traces 455 and the second pad 460 may have smooth surfaces. A second liner (not shown) may be deposited over the second traces 455 and the second pad 460 with a process similar to the process described above for forming the liner 430.

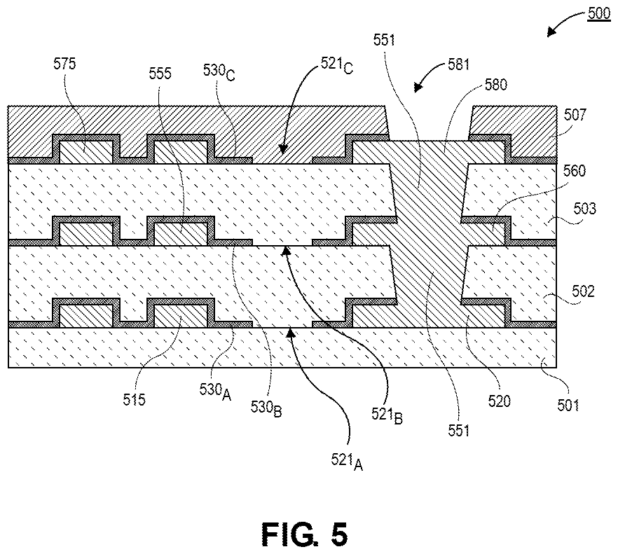

Referring now to FIG. 5, a cross-sectional illustration of a package substrate 500 is shown, in accordance with an embodiment. In an embodiment, the package substrate 500 may include a plurality of layers. For example, layers 501, 502, and 503 are shown. In an embodiment, first traces 515 and first pad 520 may be provided in the second layer 502. A first liner 530A is provided in the second layer 502. A first opening 521_{A} may be formed through the first liner 530A to provide contact between the first layer 501 and the second layer 502. In an embodiment, second traces 555 and a second pad 560 are provided in the third layer 503. A second liner 530E is provided in the third layer 503. A second opening 521E may be formed through the second liner 530E to provide contact between the second layer 502 and the third layer 503. In an embodiment, third traces 575 and a third pad 580 may be provided in a solder resist layer 507. A third liner 530_{C} is provided in the solder resist layer 507. A third opening 521_{C} may be formed through the third liner 530_{C} to provide contact between the third layer 503 and the solder resist layer 507. In the illustrated embodiment, the openings 521_{A}-521_{C} are aligned with each other. However, in other embodiments, the openings 521_{A}-521_{C} may not be aligned with each other. For example, the openings 521_{A}-521_{C} can be distributed in the various layers based on the necessary design layout of each layer. Vias 551 may electrically couple the pads 580, 560, and 520 together. In an embodiment, an opening 581 may be provided through the solder resist layer 507.

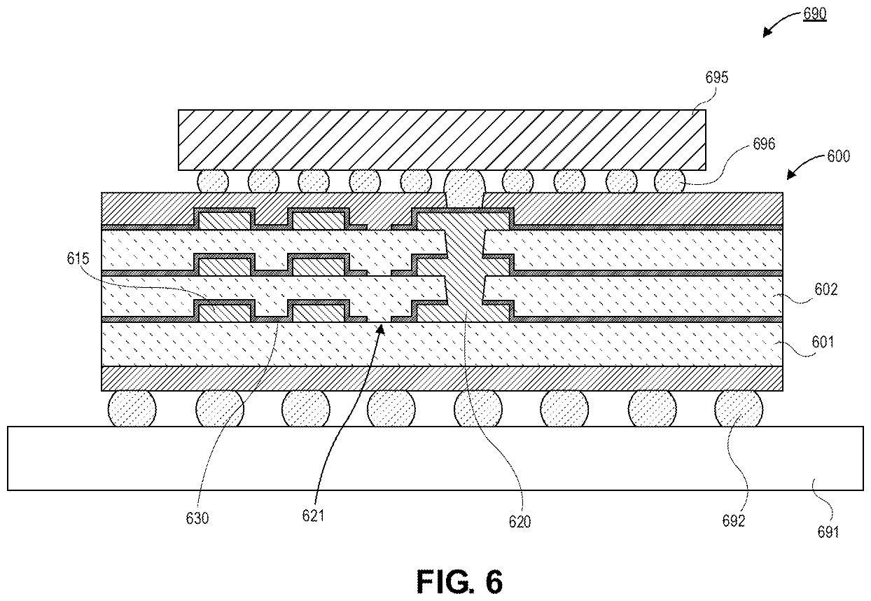

Referring now to FIG. 6, a cross-sectional illustration of an electronic system 690 is shown, in accordance with an embodiment. In an embodiment, the electronic system 600 comprises a board 691, such as a printed circuit board (PCB). The board 691 may be coupled to a package substrate 600 by interconnects 692. In an embodiment, the interconnects 692 are shown as solder balls, but it is to be appreciated that any interconnect architecture may be used. In an embodiment, a die 695 may be coupled to the package substrate 600 by interconnects 696. While shown as solder balls, it is to be appreciated that any first level interconnect (FLI) architecture may be used for interconnects 696.

In an embodiment, the package substrate 600 may comprise a first layer 601 and a second layer 602. Traces 615 and pads 620 may be provided in the second layer 602. Additionally, a liner 630 may be provided over the traces 615, the pad 620, and the first layer 601. In an embodiment, a hole 621 may be provided through the liner 630 in order to allow for moisture outgassing. In an embodiment, the liner 630 may comprise silicon and nitrogen (e.g., SiNx). While a particular package substrate 600 is shown in FIG. 6, it is to be appreciated that any package substrate in accordance with embodiments disclosed herein may be used in the electronic system.

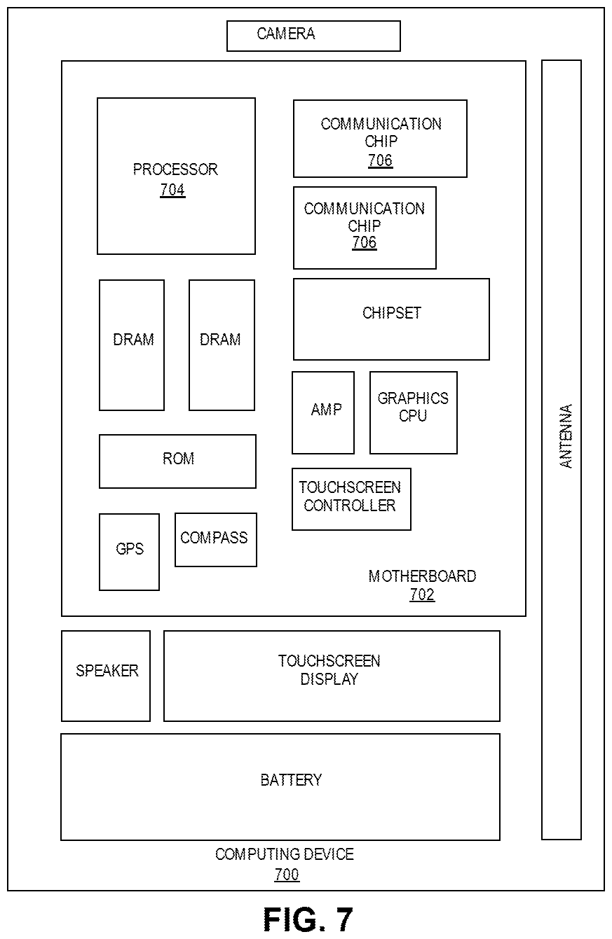

FIG. 7 illustrates a computing device 700 in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the invention, the integrated circuit die of the processor may be part of an electronic package that includes a package substrate with traces and a pad that are covered by a liner, where the liner includes a hole to allow for moisture outgassing between layers of the package substrate, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the invention, the integrated circuit die of the communication chip may be part of an electronic package that includes a package substrate with traces and a pad that are covered by a liner, where the liner includes a hole to allow for moisture outgassing between layers of the package substrate, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a first layer, wherein the first layer is a dielectric material; a trace on the first layer; a pad on the first layer; a liner over the first layer, the trace, and the pad, wherein a hole is provided through the liner; and a second layer over the first layer, the trace, the pad, and the liner.

Example 2: the electronic package of Example 1, wherein a second hole is provided through the liner over the pad.

Example 3: the electronic package of Example 2, further comprising: a via through the second layer, wherein the via lands on the pad.

Example 4: the electronic package of Example 3, wherein the via contacts the liner.

Example 5: the electronic package of Example 4, wherein the via contacts a sidewall of the liner.

Example 6: the electronic package of Example 4, wherein the via contacts a top surface of the liner.

Example 7: the electronic package of Examples 3-6, wherein the via does not contact the liner.

Example 8: the electronic package of Examples 1-7, wherein the hole is positioned between the trace and the pad.

Example 9: the electronic package of Examples 1-8, wherein the second layer contacts the first layer through the hole.

Example 10: the electronic package of Examples 1-9, wherein the liner comprises silicon and nitrogen.

Example 11: the electronic package of Examples 1-10, wherein surfaces of the trace and the pad are not roughened.

Example 12: the electronic package of Examples 1-10, wherein the liner is on sidewalls of the trace and a top surface of the trace.

Example 13: the electronic package of Examples 1-12, wherein the first layer and the second layer comprise a dielectric material.

Example 14: a method of forming an electronic package, comprising: forming a trace and a pad over a first layer; forming a mask feature over the first layer; disposing a liner over the trace, the pad, and the first layer, wherein the mask feature blocks the deposition of the liner over a portion of the first layer; removing the mask feature; and disposing a second layer over the first layer, the trace, and the pad.

Example 15: the method of Example 14, further comprising: forming a via opening through the second layer and the liner, wherein the via opening exposes a portion of the pad.

Example 16: the method of Example 14 or Example 15, further comprising: forming a second mask feature over the pad, wherein the second mask feature blocks deposition of the liner over a portion of the pad.

Example 17: the method of Examples 14-16, wherein the liner comprises silicon and nitrogen.

Example 18: a method of forming an electronic package, comprising: forming a trace and a pad over a first layer; disposing a liner over the trace, the pad, and the first layer; forming a patterned mask layer over the trace, the pad, and the first layer, wherein the patterned mask layer includes an opening to expose a region of the liner adjacent to the trace; removing the liner in the opening; and disposing a second layer over the first layer, the trace, the pad, and the liner.

Example 19: the method of Example 18, wherein the patterned mask layer further includes a second opening to expose a region of the liner over the pad.

Example 20: the method of Example 19, wherein the second layer directly contacts the first layer through a first hole in the liner, and wherein the second layer directly contacts the pad through a second hole in the liner.

Example 21: the method of Examples 18-20, further comprising: forming a via opening through the second layer, wherein the via opening exposes a portion of the pad.

Example 22: the method of Examples 18-21, wherein the liner comprises silicon and nitrogen.

Example 23: an electronic system, comprising: a board; a package substrate coupled to the board, wherein the package substrate comprises: a first layer; a trace over the first layer; a liner over the first layer and the trace, wherein a hole adjacent to the trace is provided through the liner; and a second layer over the first layer, the trace, and the liner; and a die coupled to the package substrate.

Example 24: the electronic system of Example 23, wherein the liner comprises silicon and nitrogen.

Example 25: the electronic system of Example 23 or Example 24, wherein the first layer directly contacts the second layer through the hole.

What is claimed is:

1. An electronic package, comprising:
a first layer, wherein the first layer is a dielectric material;
a trace on the first layer;
a pad on the first layer;
a liner over the first layer, the trace, and the pad, wherein a hole is provided through the liner; and
a second layer over the first layer, the trace, the pad, and the liner.

2. The electronic package of claim 1, wherein a second hole is provided through the liner over the pad.

3. The electronic package of claim 2, further comprising:
a via through the second layer, wherein the via lands on the pad.

4. The electronic package of claim 3, wherein the via contacts the liner.

5. The electronic package of claim 4, wherein the via contacts a sidewall of the liner.

6. The electronic package of claim 4, wherein the via contacts a top surface of the liner.

7. The electronic package of claim 3, wherein the via does not contact the liner.

8. The electronic package of claim 1, wherein the hole is positioned between the trace and the pad.

9. The electronic package of claim 1, wherein the second layer contacts the first layer through the hole.

10. The electronic package of claim 1, wherein the liner comprises silicon and nitrogen.

11. The electronic package of claim 1, wherein surfaces of the trace and the pad are not roughened.

12. The electronic package of claim 1, wherein the liner is on sidewalls of the trace and a top surface of the trace.

13. The electronic package of claim 1, wherein the first layer and the second layer comprise a dielectric material.

14. A method of forming an electronic package, comprising:
forming a trace and a pad over a first layer;
forming a mask feature over the first layer;
disposing a liner over the trace, the pad, and the first layer, wherein the mask feature blocks the deposition of the liner over a portion of the first layer;
removing the mask feature; and
disposing a second layer over the first layer, the trace, and the pad.

15. The method of claim 14, further comprising:
forming a via opening through the second layer and the liner, wherein the via opening exposes a portion of the pad.

16. The method of claim 14, further comprising:
forming a second mask feature over the pad, wherein the second mask feature blocks deposition of the liner over a portion of the pad.

17. The method of claim 14, wherein the liner comprises silicon and nitrogen.

18. A method of forming an electronic package, comprising:
forming a trace and a pad over a first layer;
disposing a liner over the trace, the pad, and the first layer;
forming a patterned mask layer over the trace, the pad, and the first layer, wherein the patterned mask layer includes an opening to expose a region of the liner adjacent to the trace;
removing the liner in the opening; and
disposing a second layer over the first layer, the trace, the pad, and the liner.

19. The method of claim 18, wherein the patterned mask layer further includes a second opening to expose a region of the liner over the pad.

20. The method of claim 19, wherein the second layer directly contacts the first layer through a first hole in the liner, and wherein the second layer directly contacts the pad through a second hole in the liner.

21. The method of claim 18, further comprising:
forming a via opening through the second layer, wherein the via opening exposes a portion of the pad.

22. The method of claim 18, wherein the liner comprises silicon and nitrogen.

23. An electronic system, comprising:
a board;
a package substrate coupled to the board, wherein the package substrate comprises:
a first layer;
a trace over the first layer;
a liner over the first layer and the trace, wherein a hole adjacent to the trace is provided through the liner; and
a second layer over the first layer, the trace, and the liner; and
a die coupled to the package substrate.

24. The electronic system of claim 23, wherein the liner comprises silicon and nitrogen.

25. The electronic system of claim 23, wherein the first layer directly contacts the second layer through the hole.
